(19) United States
(12) Patent Application Publication
(10) Pub. No.: US 2026/0305297 A1
(43) Pub. Date: Oct. 1, 2026

(54) INTEGRATION OF VIA AND BOTTOM ELECTRODE FOR MEMORY CELL

(71) Applicant: Taiwan Semiconductor Manufacturing Company, Ltd., Hsinchu (TW)

(72) Inventors: Tzu-Yu Chen, Kaohsiung City (TW); Wen-Ting Chu, Kaohsiung City (TW); Kuo-Chi Tu, Hsin-Chu (TW); Sheng-Hung Shih, Hsinchu City (TW)

(21) Appl. No.: 19/695,080

(22) Filed: Jun. 2, 2026

Related U.S. Application Data
(62) Division of application No. 18/316,429, filed on May 12, 2023, now Pat. No. 12,666,945.

(51) Int. Cl. H10W 20/42; H10B 51/30; H10W 20/00; H10W 20/41

(52) U.S. Cl. CPC H10W 20/42; H10B 51/30; H10W 20/033; H10W 20/062; H10W 20/075; H10W 20/081; H10W 20/435

(57) ABSTRACT

Some embodiments relate to a method of forming an integrated chip, including forming a first wire level over a substrate; depositing an etch stop layer over the first wire level; etching the etch stop layer to form an opening over the first wire level; depositing a barrier layer over the etch stop layer, the barrier layer extending into the opening; depositing a first conductive layer over the barrier layer and in the opening; performing a planarization into the first conductive layer to flatten a top of the first conductive layer, wherein the planarization stops before reaching the barrier layer; depositing a data storage layer and a second conductive layer over the first conductive layer; and patterning the barrier layer, the first conductive layer, the data storage layer, and the second conductive layer to form a memory cell at the opening.

### REFERENCE TO RELATED APPLICATION

This Application is a Divisional of U.S. application Ser. No. 18/316,429, filed on May 12, 2023, the contents of which are hereby incorporated by reference in their entirety.

### BACKGROUND

Many modern day electronic devices include non-volatile memory. Non-volatile memory is electronic memory that is able to store data in the absence of power. A promising candidate for the next generation of non-volatile memory is ferroelectric random-access memory (FeRAM). FeRAM has a relatively simple structure and is compatible with complementary metal-oxide-semiconductor (CMOS) logic fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip comprising a memory cell with a bottom via and a bottom electrode integrated into a first conductive layer.

FIG. 2 illustrates a cross-sectional view of some embodiments of an integrated chip comprising a memory cell with a bottom via and a bottom electrode integrated into a first conductive layer.

FIGS. 3A-3B illustrate cross-sectional views of some embodiments of an integrated chip comprising a memory cell with a bottom via and a bottom electrode integrated into a first conductive layer.

FIG. 4 illustrates a cross-sectional view of some embodiments of an integrated chip comprising a memory cell with a bottom via and a bottom electrode integrated into a first conductive layer.

FIGS. 5-23 illustrate a series of cross-sectional views of some embodiments of a method for forming an integrated chip comprising a memory cell with a bottom via and a bottom electrode integrated into a first conductive layer.

FIG. 24 illustrates a flow diagram of some embodiments of a method for forming an integrated chip comprising a memory cell with a bottom via and a bottom electrode integrated into a first conductive layer.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A ferroelectric tunnel junction (FTJ) device is a type of ferroelectric random access memory (FeRAM) device that comprises a ferroelectric segment sandwiched between a bottom electrode and a top electrode. The FTJ device is partially formed by depositing an etch stop layer over an underlying wire level, etching an opening into the etch stop layer to expose the wire level, depositing a first conductive material in the opening to form a bottom via, performing a planarization process (e.g., a chemical mechanical planarization process) to remove portions of the first conductive material above the etch stop layer, depositing a second conductive layer over the etch stop layer, and performing a second planarization process to planarize the second conductive layer. A ferroelectric film and the third conductive layer are then deposited. The second conductive layer, the ferroelectric film, and the third conductive film are then patterned into the bottom electrode, the ferroelectric segment, and the top electrode, respectively. The first conductive layer may be separated from the etch stop layer by a barrier layer.

The first and second planarization steps remove excess conductive material and prepare corresponding surfaces for the depositions respectively of the second conductive layer and the ferroelectric film, while separately defining top surfaces of a bottom via and the bottom electrode. A low uniformity in the surface of the second conductive layer (e.g., by not performing a planarization process) may lead to a high degree of variation with, and degradation of, properties of the ferroelectric segment. For example, remanent polarization may have a high degree of variation, whereby bulk manufacturing yields may be low. As another example, remanent polarization may be degraded, whereby read operations may be prone to failure. Therefore, achieving a high degree of uniformity in the surface of the second conductive layer (e.g., by performing a planarization process) may be desirable. However, planarization processes are expensive and time-consuming, such that increasing the number of planarization processes performed results in reduced fabrication efficiency and high process costs.

To reduce the process costs and increase the fabrication efficiency of an integrated chip comprising a memory cell (e.g., a ferroelectric tunnel junction (FTJ) cell or the like), various embodiments of the present disclosure are directed towards a method of forming a bottom via and a bottom electrode of a memory cell using a single conductive layer. The conductive layer extends through an opening in an etch stop layer to electrically couple to an underlying wire level. A first portion of the conductive layer in the opening functions as a bottom via. The conductive layer further extends over an uppermost surface of the etch stop layer. A single planarization process is performed on the conductive layer, resulting in the conductive layer having a planarized surface extending over the uppermost surface of the etch stop layer. A second portion of the conductive layer is between the uppermost surface of the etch stop layer and the planarized surface of the conductive layer, where the second portion is configured to function as a bottom electrode. The ferroelectric film and a second conductive layer are then formed over the first conductive layer. The second conductive layer, the ferroelectric film, and the first conductive layer are patterned, forming a top electrode, a ferroelectric segment, and a conductive structure of a memory cell.

In a completed memory cell, the conductive structure functions as both a bottom via and a bottom electrode. A portion of the conductive structure in the opening couples the memory cell to the underlying wire level, and a portion of the conductive structure over the opening evenly applies a bias voltage to one side of the ferroelectric segment during operation. Removing a planarization process from the method while maintaining a uniform surface to deposit the ferroelectric film over results in a manufacturing process with reduced process time and costs without sacrificing functionality or yields, leading to greater fabrication efficiency.

FIG. 1 illustrates a cross-sectional view 100 of some embodiments of an integrated chip comprising a memory cell with a bottom via and a bottom electrode integrated into a first conductive layer.

The integrated chip comprises a memory cell 101 over a substrate 104. In some embodiments, the memory cell 101 is or comprises an FTJ cell or the like. The memory cell 101 is in a first region I of the integrated chip and is integrated into an interconnect structure 105. The memory cell 101 is sandwiched between lower wires 106 (only one of which is shown) and upper wires 132 (only one of which is shown). The lower wires 106 are surrounded by a first dielectric layer 108 of a plurality of intermetal dielectric (IMD) layers. The lower wires 106 and the first dielectric layer 108 are part of a first wire level 102. The upper wires 132 and the memory cell 101 are surrounded by a second dielectric layer 128 of the plurality of IMD layers. A first spacer 120, a second etch stop layer 124, a buffer layer 126, and a hard mask layer 122 extend between the memory cell 101 and the second dielectric layer 128.

The memory cell 101 comprises a conductive structure 114, a ferroelectric segment 116, and a top electrode 118. The conductive structure 114 overlies a first etch stop layer 110, and has a first portion 113 extending into the first etch stop layer 110. A barrier layer 112 spaces the conductive structure 114 from the first wire level 102 and the first etch stop layer 110. In some embodiments, the first portion 113 of the conductive structure 114 is confined between inner sidewalls of the barrier layer, while a second portion 115 of the conductive structure 114 is confined above a topmost surface 112t of the barrier layer 112. The conductive structure 114 has a planarized surface 114t that extends directly over topmost surfaces of the barrier layer 112 and the etch stop layer 110. The barrier layer 112 spaces the planarized surface 114t of the conductive structure 114 from the first etch stop layer 110.

The ferroelectric segment 116 separates the conductive structure 114 from the top electrode 118. The ferroelectric segment 116 may have a first polarization and a second polarization, respectively represented by a first data state (e.g., logical “0”) and a second state (e.g., logical “1”). The polarization of the ferroelectric segment 116 is set by applying either a first voltage or a second voltage across the ferroelectric segment 116. The voltages are applied through biasing the top electrode 118 and the conductive structure 114. The top electrode 118 is electrically coupled to upper wires 132 by a top via 130. The second portion 115 of the conductive structure 114 functions as a bottom electrode, and is electrically coupled to the lower wires 106 by the first portion 113 and the barrier layer 112, which together function as a via.

The method of forming the memory cell 101 described further on in this disclosure reduces the number of planarization steps used in forming the conductive structure 114. The conductive structure 114 combines the functionality of a bottom via and a bottom electrode into a single feature with no loss in performance. A lower number of planarization processes performed results in a shorter manufacturing time and a more cost efficient design while maintaining the uniformity of the planarized surface 114t that reinforces the ferroelectric properties of the ferroelectric segment 116.

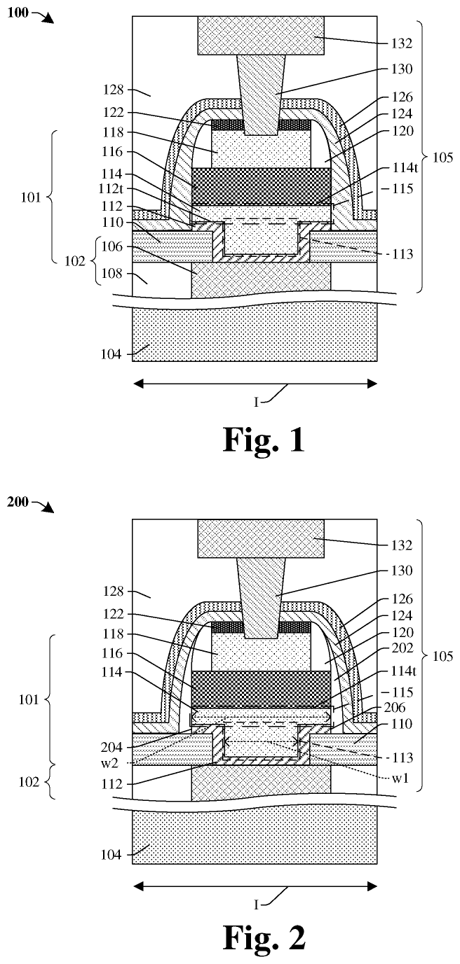

FIG. 2 illustrates a cross-sectional view 200 of some embodiments of an integrated chip comprising a memory cell with a bottom via and a bottom electrode integrated into a first conductive layer.

The first spacer 120 overlies the ferroelectric segment 116 and covers outer sidewalls of the top electrode 118 and the hard mask layer 122. In some embodiments, a second spacer 202 overlies the first etch stop layer 110 and extends up outer sidewalls of the barrier layer 112, the conductive structure 114, and the ferroelectric segment 116. In some embodiments, the second etch stop layer 124 covers and conforms to the memory cell 101, the first spacer 120, the second spacer 202, and the first etch stop layer 110. In further embodiments, the buffer layer 126 covers and conforms to the second etch stop layer 124.

In some embodiments, the barrier layer 112 extends from a first outer sidewall 204 directly beneath a first edge of the planarized surface 114t to a second outer sidewall 206 directly beneath a second edge of the planarized surface 114t opposite the first edge. In some embodiments, the etch stop layer 110 surrounds the first portion 113 of the conductive structure 114, wherein the etch stop layer 110 is directly between the second portion 115 of the conductive structure 114 and the first wire level 102, and wherein the etch stop layer 110 is separated from the conductive structure 114 by the barrier layer 112. In some embodiments, an upper surface of the barrier layer 112 is at an elevation level with both a top of the first portion 113 and a bottom of the second portion 115 of the conductive structure 114.

In some embodiments, the first portion 113 is configured to function as a bottom via and has a first width w1, and the second portion 115 is configured to function as a bottom electrode and has a second width w2 that is greater than the first width w1 and is equal to a width of the barrier layer. In some embodiments, the second portion 115 of the conductive structure 114 is a pad and the first portion 113 is a protrusion extending through the etch stop layer from the pad, wherein the protrusion has a substantially constant first width w1, and wherein the pad overlies the etch stop structure and the protrusion and has a substantially constant second width w2, wherein the second width w2 is greater than the first width w1. In further embodiments, the pad and the protrusion of the conductive structure 114 form a “T” shape when viewed from a cross-sectional view, and wherein the barrier layer 112 extends along bottom surfaces of the “T” shape. In some embodiments, the barrier layer 112, the conductive structure 114, and the ferroelectric segment 116 form a common sidewall directly over the etch stop layer 110. In further embodiments, the barrier layer 112 has an outer sidewall facing a same direction as the common sidewall and directly between inner sidewalls of the etch stop layer 110.

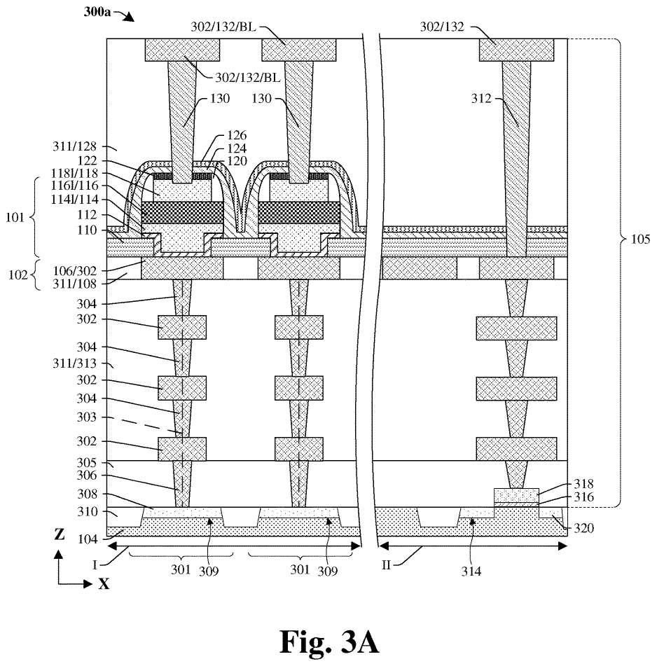

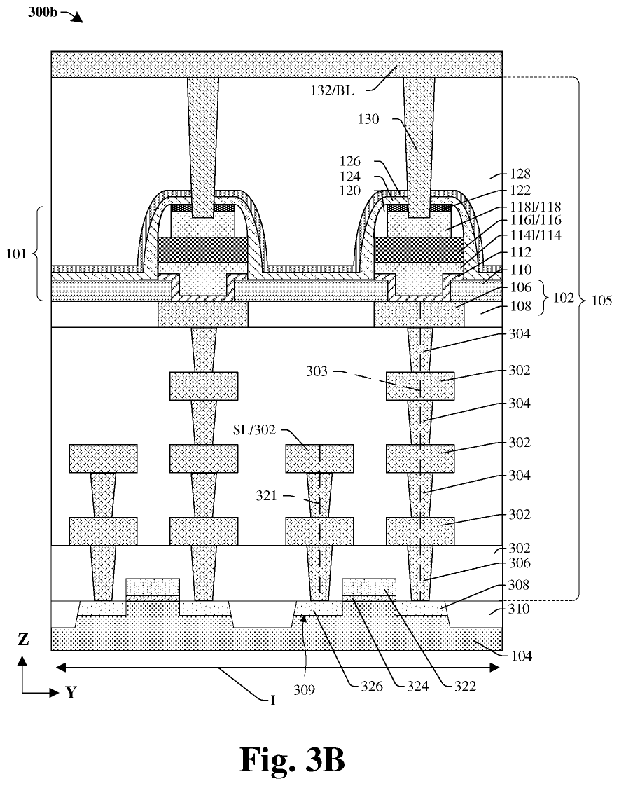

FIGS. 3A-3B illustrate cross-sectional views of some embodiments of an integrated chip comprising a memory cell with a bottom via and a bottom electrode integrated into a first conductive layer, where the memory cells 101 are further integrated into individual one-transistor one-resistor (1T1R) cells 301. The memory cells are each as their counterpart is described with regard to FIG. 1.

The 1T1R cells 301 comprise individual drain regions 308 and individual drain-side conductive paths 303. The drain regions 308 are doped regions of a substrate 104 and each has an opposite doping type as an adjoining region of the substrate 104. Further, the drain regions 308 are electrically separated by a trench isolation structure 310 and partially define access transistors 309 (partially shown) used to individually select the memory cells 101. The trench isolation structure 310 extends into a top of the substrate 104 and comprises silicon oxide and/or some other suitable dielectric material(s). The substrate 104 may, for example, be a bulk silicon substrate or some other suitable semiconductor substrate.

The drain-side conductive paths 303 electrically couple the drain regions 308 to the memory cells 101 and are formed by an interconnect structure 105 within which the memory cells 101 are arranged. The interconnect structure 105 comprises a plurality of wires 302 and a plurality of vias 304. The plurality of wires 302 comprises the lower wires 106 and the upper wires 132. In some embodiments, the upper wires 132 coupled to the memory cells 101 correspond to bit lines BL. The plurality of vias 304 comprises TEVAs. A plurality of contacts 306 electrically couples the drain regions 308 to the plurality of wires 302. The plurality of contacts 306 is in an interlayer dielectric (ILD) layer 305, whereas the plurality of vias 304 and the plurality of wires 302 are in IMD layers 311. The IMD layers 311 comprise the first dielectric layer, the second dielectric layer, and the intermediate dielectric layers 313. The plurality of wires 302 and the plurality of vias 304, may be or comprise, for example, copper, aluminum, some other suitable metal(s), or any combination of the foregoing.

A peripheral region II to a side of the 1T1R cells 301 accommodates peripheral devices 314 (only one of which is shown). The peripheral devices 314 may, for example, be metal-oxide-semiconductor field-effect transistors (MOSFETs), fin field-effect transistors (finFETs), gate-all-around field-effect transistors (GAA FETs), or some other suitable type of semiconductor device. Each of the peripheral devices 314 comprises a pair of source/drain regions 320 in the substrate 104, as well as a gate electrode 318 and a gate dielectric layer 316 stacked between the source/drain regions 320. A conductive path in the second region II couples the peripheral devices 314 to extended vias 312. The extended vias 312 electrically couple the lower wires 106 to the upper wires 132, and extend from an elevation level with a bottom of the barrier layer 112 to an elevation level with a top of the top via 130.

With reference to FIG. 3B, a cross-sectional view 300b of some embodiments of the IC chip of FIG. 300a is provided along an axis orthogonal to that which the cross-sectional view 300a of FIG. 3A is taken. The 1T1R cells 301 comprise individual memory cells 101, individual drain-side conductive paths 303, individual access transistors 309, and individual source-side conductive paths 321. The memory cells 101 are each as their counterpart is described with regard to FIG. 1.

The access transistors 309 are on the substrate 104, between the substrate 104 and the interconnect structure 105, and are electrically separated by the trench isolation structure 310. The access transistors 309 comprise individual drain regions 308, individual source regions 326, individual gate dielectric layers 324, and individual gate electrodes 322. The gate electrodes 322 respectively overlie the gate dielectric layers 324 and, in some embodiments, form word lines. The drain and source regions 308, 326 are doped regions of the substrate 104 and each has an opposite doping type as an adjoining region of the substrate 104. Further, the drain and source regions 308, 326 respectively border the gate electrodes 322. The access transistors 309 may, for example, be MOSFETs, finFETs, GAA FETs, or some other suitable type of semiconductor device.

The drain-side conductive paths 303 electrically couple the drain regions 308 to the memory cells 101, and the source-side conductive paths 321 electrically couple the source regions 326 to source lines SL. The drain-side and source-side conductive paths 303, 321 are formed by the plurality of wires 302, the plurality of vias 304, and the plurality of contacts 306.

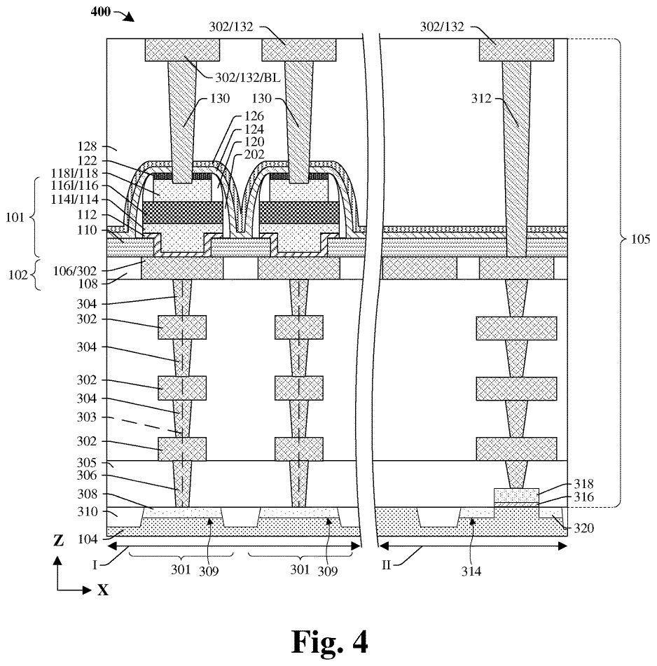

While FIGS. 3A and 3B are illustrated using memory-cell embodiments as in FIG. 1, memory-cell embodiments as in FIG. 2 are amenable in alternative embodiments. For example, as illustrated by the cross-sectional view 400 of FIG. 4, the memory cells 101 of FIGS. 3A-3B may alternatively be configured as in FIG. 2.

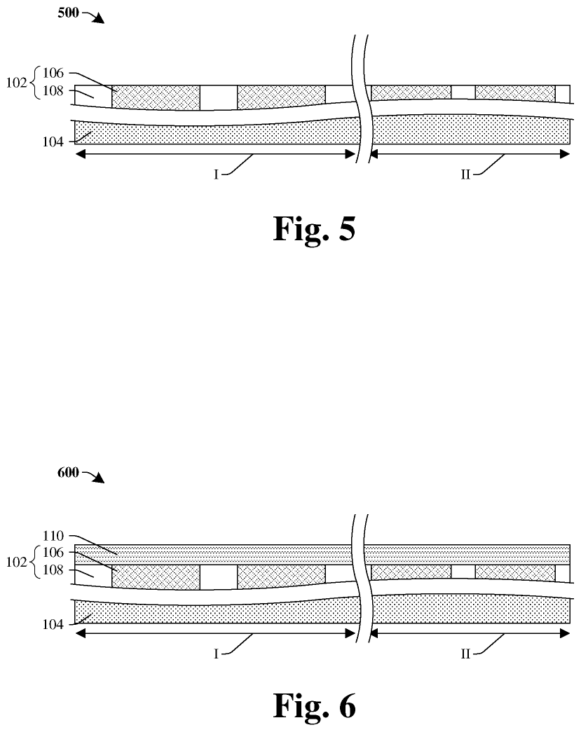

FIGS. 5-23 illustrate a series of cross-sectional views of some embodiments of a method for forming an integrated chip comprising a memory cell with a bottom via and a bottom electrode integrated into a first conductive layer. The method may, for example, be employed to form the integrated chip of FIG. 4 or the like. Although FIGS. 5-23 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. The portion of the interconnect structure 105 below the first wire level 102 is not shown in FIGS. 5-23 for ease of clarity.

As shown in the cross-sectional view 500 of FIG. 5, the first wire level 102 is formed over the substrate 104. The first wire level 102 comprises the lower wires 106 spaced by the first dielectric layer 108 of the IMD layers 311 (See FIG. 3A). In some embodiments, the lower wires 106 are or comprise one of polysilicon, copper (e.g., Cu), titanium nitride (e.g., TiN), tungsten (e.g., W), aluminum (e.g., Al), tantalum nitride (e.g., TaN), the like, or any combination of the foregoing. In some embodiments, the first wire level 102 extends over a first region I and a second region II of the integrated chip.

As shown in the cross-sectional view 600 of FIG. 6, the etch stop layer 110 is deposited over the first wire level 102 in the first region I and in the second region II. In some embodiments, the etch stop layer 110 may, for example, be deposited by a physical vapor deposition (PVD), a chemical vapor deposition (CVD), or an atomic layer deposition (ALD) process, and may be or comprise a nitride (e.g., silicon nitride), a carbide (e.g., silicon carbide), an oxide, the like, or any combination of the foregoing.

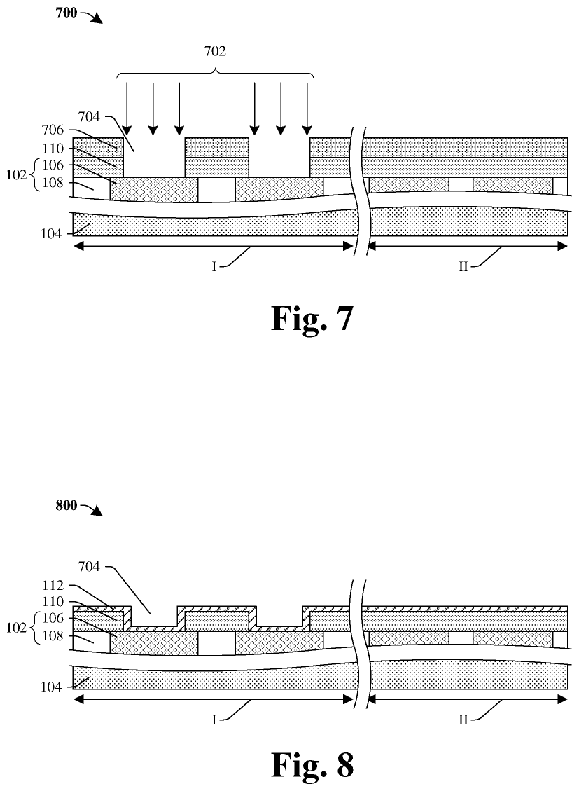

As shown in the cross-sectional view 700 of FIG. 7, the etch stop layer 110 is patterned by a first etching process 702, forming an opening 704 in the etch stop layer 110. The patterning comprises forming a first masking layer 706 (e.g., positive/negative photoresist, a hard mask, etc.) over the etching layer. The first masking layer 706 is formed by depositing the first masking layer 706 (e.g., via a spin-on process), and then patterning the first masking layer 706 (e.g., via a lithography process, such as extreme ultraviolet lithography, or the like). The pattern is such portions of the etch stop layer 110 corresponding to the opening 704 are exposed to the first etching process 702. The first etching process 702 is then performed, etching the etch stop layer 110 according to the pattern of the first masking layer 706. The first etching process 702 is or comprises a wet etching process, a dry etching process, or some other suitable etching process. The first masking layer 706 is then removed. In some embodiments, the first masking layer 706 is removed using one or more etching processes, one or more stripping processes, one or more ashing processes, some other process, or a combination of the foregoing.

As shown in the cross-sectional view 800 of FIG. 8, the barrier layer 112 is deposited over the etch stop layer 110. The barrier layer 112 extends into the opening 704. In some embodiments, the barrier layer 112 is or comprises one of a metal (e.g., nickel), a nitride (e.g., tantalum nitride, titanium nitride), other conductive material(s), or any combination of the foregoing. In some embodiments, the barrier layer 112 may, for example, be deposited by a PVD, CVD, or ALD process.

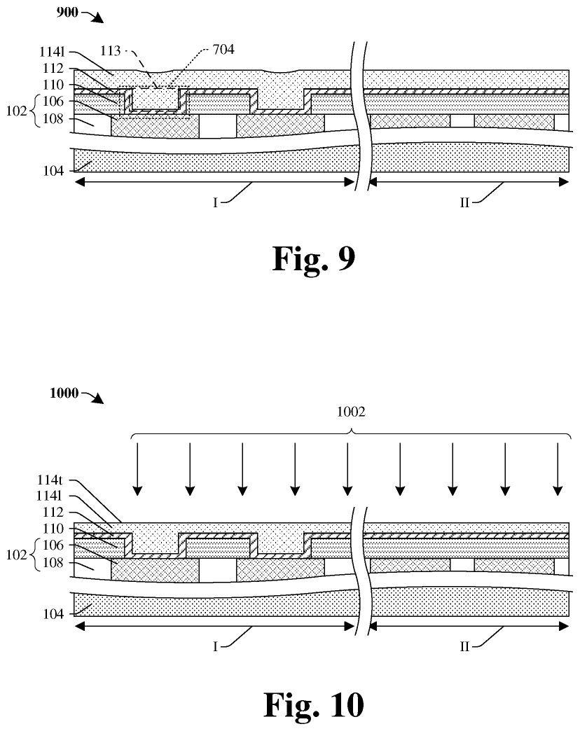

As shown in the cross-sectional view 900 of FIG. 9, the first conductive layer 114l is deposited over the barrier layer 112. The first portion 113 of the first conductive layer 114l fills the opening 704 (shown in phantom), and covers the barrier layer 112. The opening 704 defines the first portion 113, which is configured to function as a bottom via. Conductive material that will form the second portion 115 (See FIG. 2) is also deposited in this process. Depositing both the first portion 113 and the second portion 115 of the conductive structure 114 in one deposition process removes a planarization step from the manufacturing process, thereby lowering the time and expense required to form the integrated chip.

In some embodiments, the first conductive layer 114l has an uneven top surface extending over the opening 704. In some embodiments, the first conductive layer 114l may, for example, be deposited by a PVD, CVD, or ALD process. In some embodiments, the deposition of the first conductive layer 114l is performed using a first deposition step, where the first portion 113 and the second portion 115 of the conductive structure 114 are formed during the first deposition step.

As shown in the cross-sectional view 1000 of FIG. 10, a planarization process 1002 is performed on the first conductive layer 114l. The planarization process 1002 results in the first conductive layer 114l having a planarized surface 114t. The planarized surface 114t extends directly over topmost surfaces of the etch stop layer 110 and the barrier layer 112. The barrier layer 112 spaces the planarized surface 114t of the first conductive layer 114l from the etch stop layer 110. In some embodiments, the planarization process 1002 may be, for example, a chemical-mechanical planarization (CMP) process or some other suitable planarization process.

A single CMP process being used to form the first conductive layer 114l lowers the time and expense needed to form the memory cell 101 (See FIG. 1) while maintaining the planarized surface conducive to high yields and the beneficial properties of the ferroelectric segments 116 (see FIG. 1). For example, while an uneven surface may degrade the remanent polarization of the ferroelectric segment 116, this property may be reinforced in a highly uniform surface.

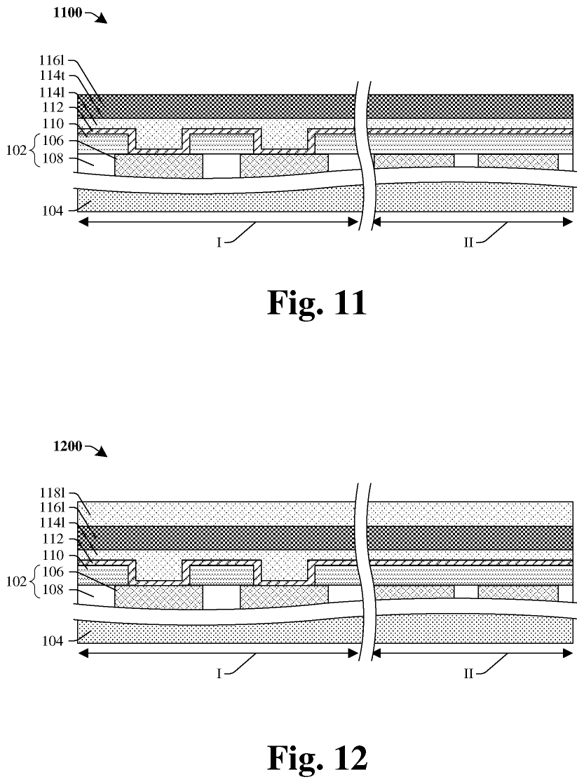

As shown in the cross-sectional view 1100 of FIG. 11, the ferroelectric film 116l is deposited over the planarized surface 114t of the first conductive layer 114l. The deposition may, for example, be performed by CVD, PVD, ALD, the like, or any combination of the foregoing. In some embodiments, the ferroelectric film 116l is or comprises a binary oxide, a ternary oxide or nitride, a quaternary oxide, some other suitable ferroelectric material(s), or any combination of the foregoing. The binary oxide may, for example, be or comprise hafnium oxide (e.g., hafnia or HfO₂) and/or some other suitable binary oxide(s). In some embodiments, the ferroelectric film may more generally be a data storage layer.

As shown in the cross-sectional view 1200 of FIG. 12, the second conductive layer 118l is deposited over the ferroelectric film 116l. The deposition may, for example, be performed by CVD, PVD, ALD, the like, or any combination of the foregoing. The first and second conductive layers 114l, 118l are or comprise copper, aluminum, tungsten, the like, or any combination of the foregoing.

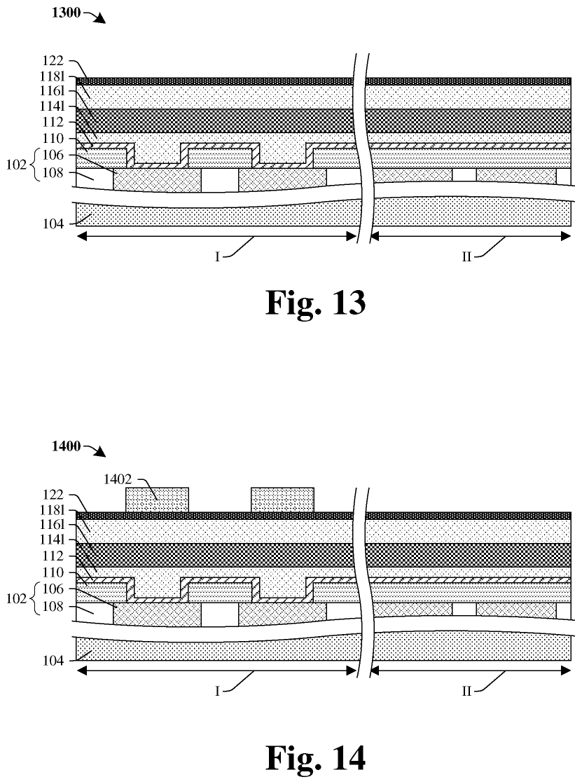

As shown in the cross-sectional view 1300 of FIG. 13, the hard mask layer 122 is deposited over the second conductive layer 118l. The deposition may, for example, be performed by CVD, PVD, ALD, the like, or any combination of the foregoing. The hard mask layer 122 may, for example, be or comprise titanium nitride, silicon oxide, silicon nitride, silicon carbide nitride, silicon oxide nitride, metal oxide, some other suitable material(s), or any combination of the foregoing.

As shown in the cross-sectional view 1400 of FIG. 14, a second masking layer 1402 is formed over the hard mask layer 122. In some embodiments, the second masking layer 1402 is patterned to cover portions of the second conductive layer 118l corresponding to the top electrode 118 of FIG. 1. In some embodiments, the second masking layer 1402 is formed by depositing the second masking layer 1402 (e.g., via a spin-on process), and then patterning the second masking layer 1402 (e.g., via a lithography process, such as extreme ultraviolet lithography, or the like).

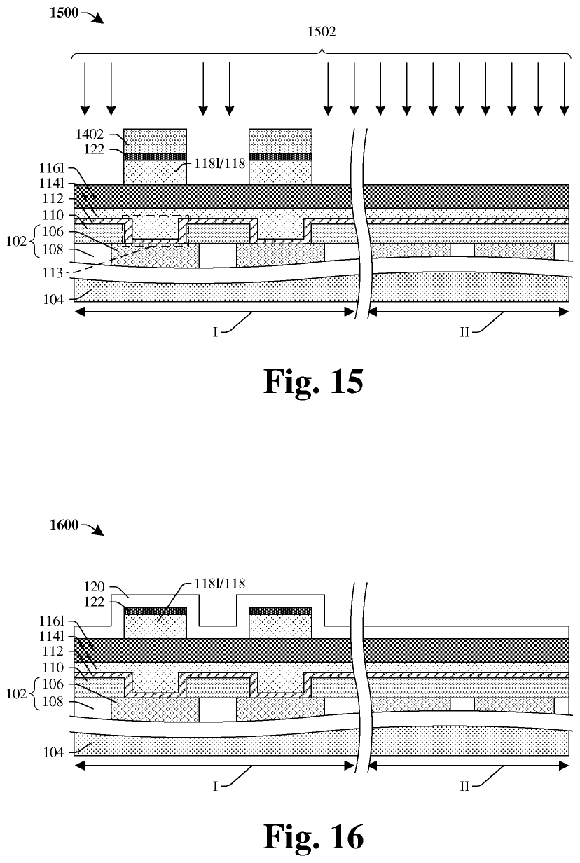

As shown in the cross-sectional view 1500 of FIG. 15, the hard mask layer 122 and the second conductive layer 118l are patterned by a second etching process 1502 according to the pattern of the second masking layer 1402. The second etching process 1502 exposes the ferroelectric film 116l and defines a top electrode 118 over the first portion 113. The second etching process 1502 is or comprises a wet etching process, a dry etching process, or some other suitable etching process.

As shown in the cross-sectional view 1600 of FIG. 16, the second masking layer 1402 is removed. Further, a first spacer layer 120l is deposited over the portions of the ferroelectric film 116l exposed by the second etching process 1502 (See FIG. 15). The first spacer layer 120l surrounds the top electrode 118. In some embodiments, the first spacer layer 120l is or comprises titanium nitride, silicon oxide, silicon nitride, silicon carbide nitride, silicon oxide nitride, a metal oxide, some other suitable material(s), or any combination of the foregoing. The deposition may, for example, be performed by CVD, PVD, ALD, the like, or any combination of the foregoing.

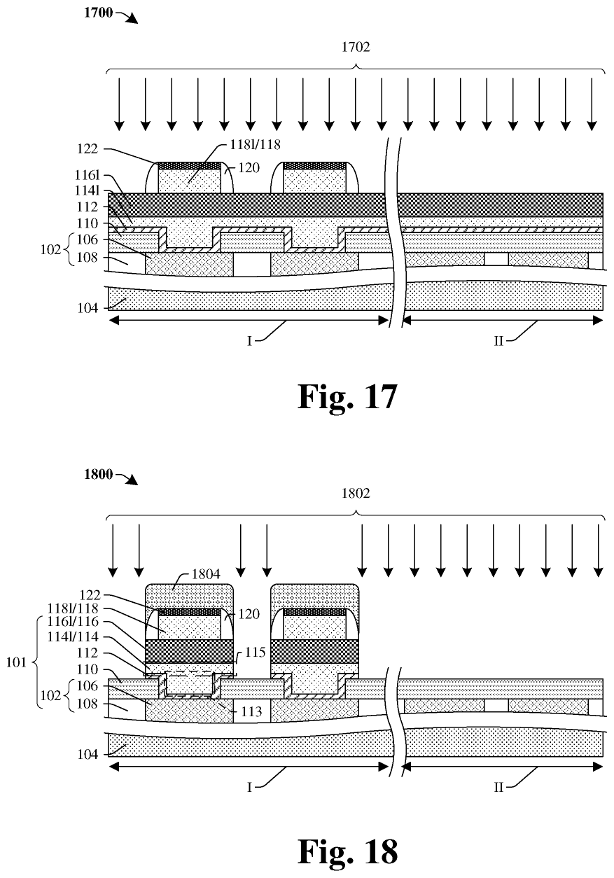

As shown in the cross-sectional view 1700 of FIG. 17, an etch back 1702 is performed on the first spacer layer 120l to form the first spacer 120. The etch back may, for example, be performed by a vertical and/or anisotropic etch or the like. The etch back removes horizontal segments of the first spacer layer 120l, thereby localizing the first spacer 120 to sidewalls (e.g., sidewalls of the top electrode 118).

As shown in the cross-sectional view 1800 of FIG. 18, a third etching process 1802 is performed, removing portions of the ferroelectric film 116l, the first conductive layer 114l, and the barrier layer 112. In some embodiments, a third masking layer 1804 is formed over the hard mask layer 122 and the first spacer 120, leaving portions of the ferroelectric film 116l exposed to the third etching process 1802. The third etching process 1802 segments the ferroelectric film 116l into portions individual to the memory cells being formed, such as the ferroelectric segment 116. In some embodiments, the ferroelectric segment may more generally be a data storage structure. The third etching process 1802 further segments the first conductive layer 114l into segments individual to the memory cells 101 being formed, such as the conductive structure 114. In some embodiments, the third etching process 1802 defines outermost sidewalls of the second portion 115 of the conductive structure 114. The second portion 115 of the conductive structure 114 is configured to function as a bottom electrode of the memory cell 101. The third etching process 1802 results in the outermost sidewalls of the barrier layer 112 being aligned with the outermost sidewalls of the conductive structure 114 and the ferroelectric segment 116, such that the topmost surface of the barrier layer 112 extends to an outermost sidewall of the conductive structure 114. In some embodiments, the third etching process 1802 is or comprises a wet etching process, a dry etching process, or some other suitable etching process.

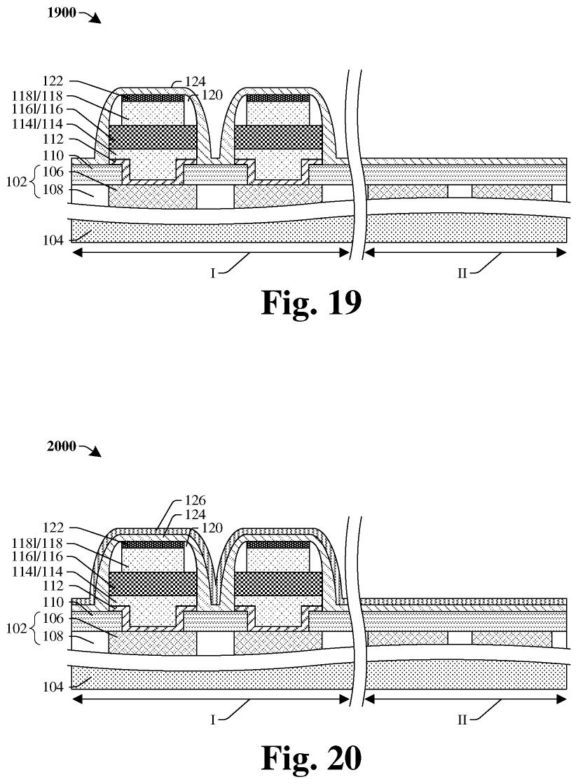

As shown in the cross-sectional view 1900 of FIG. 19, the second etch stop layer 124 is deposited over the memory cell 101. The second etch stop layer 124 covers and conforms to the first etch stop layer 110 and the memory cell 101. In some embodiments, the second etch stop layer 124 extends over the second region II. In some embodiments, the second etch stop layer 124 comprises a same material as the first etch stop layer 110. The deposition may, for example, be performed by CVD, PVD, ALD, the like, or any combination of the foregoing.

As shown in the cross-sectional view 2000 of FIG. 20, the buffer layer 126 is deposited over the second etch stop layer 124. The buffer layer 126 covers and conforms to the second etch stop layer 124. In some embodiments, the buffer layer 126 is or comprises tetraethyl orthosilicate (TEOS) oxide and/or some other suitable dielectric(s). In some embodiments, the buffer layer 126 extends over the second region II. The deposition may, for example, be performed by CVD, PVD, ALD, the like, or any combination of the foregoing.

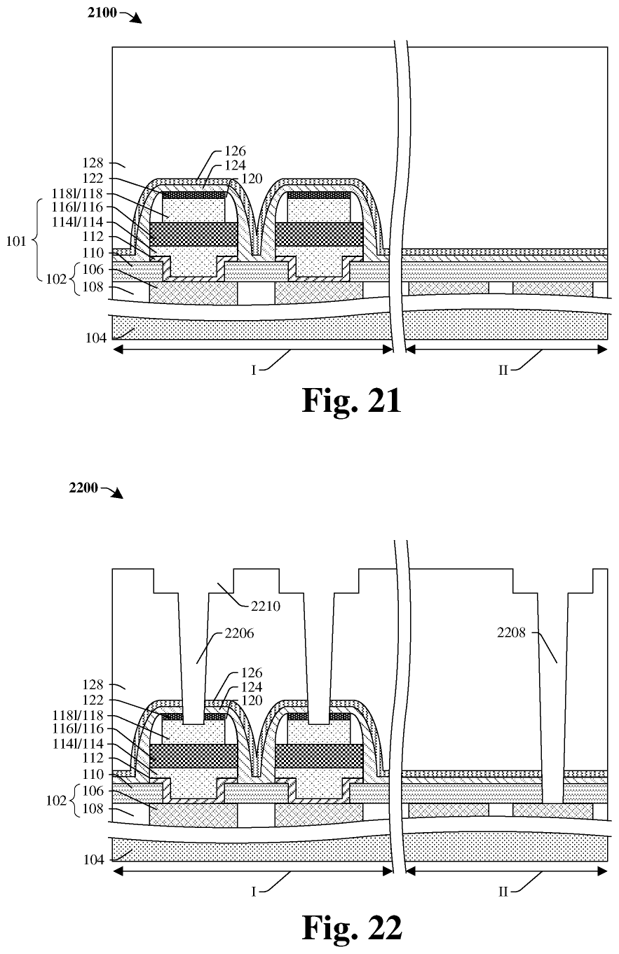

As shown in the cross-sectional view 2100 of FIG. 21, the second dielectric layer 128 of the IMD layers 311 is deposited over the first and second regions I, II. In some embodiments, the second dielectric layer 128 comprises a same material as a first dielectric layer 108. The second dielectric layer 128 covers the memory cell 101. The deposition may, for example, be performed by CVD, PVD, ALD, the like, or any combination of the foregoing.

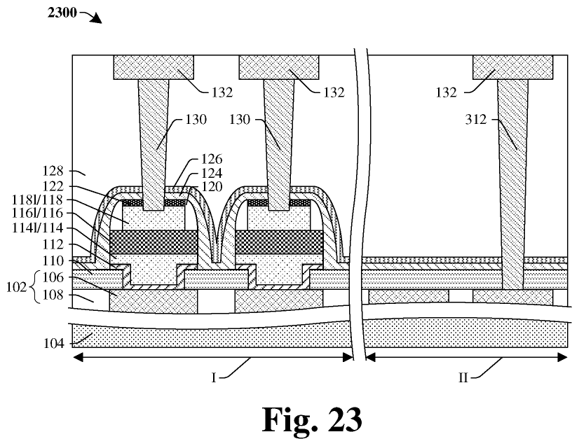

As shown in the cross-sectional view 2200 of FIG. 22, a first and second plurality of via openings 2206, 2208 are formed in the second dielectric layer 128. In some embodiments, the first and second plurality of via openings 2206, 2208 extend through the second dielectric layer 128 and the second etch stop layer 124. In some embodiments, the first region I has a first plurality of via openings 2206 that extend to a first depth within the second dielectric layer 128 and the second region II has a second plurality of via openings 2208 that extend to a second depth within the second dielectric layer 128. In further embodiments, the second depth is greater than the first depth. The first plurality of via openings 2206 extend into the top electrode 118. In some embodiments, the first and second plurality of via openings 2206, 2208 are formed using one or more etching steps and one or more masking steps. In some embodiments, a planarization process may be performed on the second dielectric layer 128 before or after the one or more etching steps and the one or more masking steps are performed.

Also shown in FIG. 22 are wire openings 2210 in the second dielectric layer 128. The wire openings 2210 overly the first and second plurality of via openings 2206, 2208. The wire openings 2210 are formed using one or more etching steps and one or more masking steps.

As shown in the cross-sectional view 2300 of FIG. 23, the top via 130, extended vias 312, and the upper wires 132 are formed within the second dielectric layer 128. The top via 130, extended vias 312, and the upper wires 132 are formed by filling the first and second plurality of via openings 2206, 2208 and the wire openings 2210 with a conductive material. The filling of the first and second plurality of via openings 2206, 2208 and the wire openings 2210 may be completed using CVD, PVD, ALD, the like, or any combination of the foregoing. A planarization process is then performed to remove portions of the conductive material above the top surface of the second dielectric layer 128. In some embodiments, the second dielectric layer 128 is not planarized until after the upper wires 132 are formed. The top via 130 extends from an elevation level with the upper wires 132 to an elevation level with a top surface of the top electrode 118.

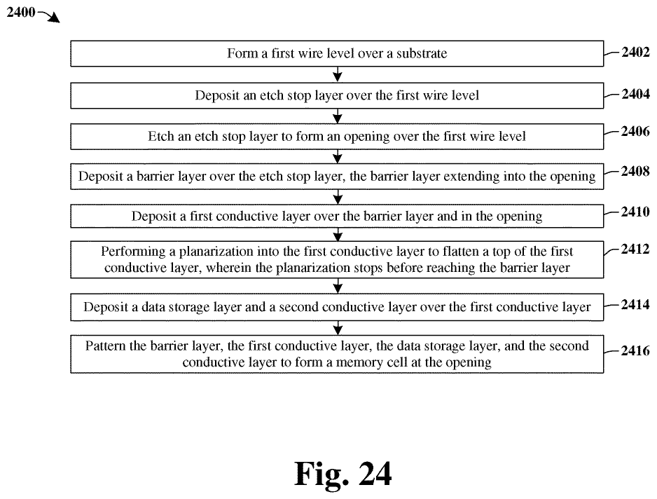

FIG. 24 illustrates a flow diagram 2400 of some embodiments of a method for forming an integrated chip comprising a memory cell with a bottom via and a bottom electrode integrated into a first conductive layer.

While the method is illustrated and described below as a series of acts or events, it will be appreciated that the illustrated ordering of such acts or events is not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 2402, a first wire level is formed over a substrate. See, for example, FIG. 5.

At 2404, an etch stop layer is deposited over the first wire level. See, for example, FIG. 6.

At 2406, the etch stop layer is etched to form an opening over the first wire level. See, for example, FIG. 7.

At 2408, a barrier layer is deposited over the etch stop layer, the barrier layer extending into the opening. See, for example, FIG. 8.

At 2410, a first conductive layer is deposited over the barrier layer and in the opening. See, for example, FIG. 9.

As 2412, a planarization is performed into the first conductive layer, flattening a top of the first conductive layer, wherein the planarization stops before reaching the barrier layer. See, for example, FIG. 10.

As 2414, a data storage layer and a second conductive layer are deposited over the first conductive layer. See, for example, FIGS. 11-12.

At 2416, the barrier layer, the first conductive layer, the data storage layer, and the second conductive layer are patterned to form a memory cell at the opening. See, for example, FIGS. 14-18.

Therefore, the present disclosure relates to a method of forming an integrated chip comprising a memory cell with a bottom via and a bottom electrode integrated into a first conductive layer.

Some embodiments relate to a method of forming an integrated chip, including forming a first wire level over a substrate; depositing an etch stop layer over the first wire level; etching the etch stop layer to form an opening over the first wire level; depositing a barrier layer over the etch stop layer, the barrier layer extending into the opening; depositing a first conductive layer over the barrier layer and in the opening; performing a planarization into the first conductive layer to flatten a top of the first conductive layer, wherein the planarization stops before reaching the barrier layer; depositing a data storage layer and a second conductive layer over the first conductive layer; and patterning the barrier layer, the first conductive layer, the data storage layer, and the second conductive layer to form a memory cell at the opening.

In other embodiments, the present disclosure relates to a method of forming an integrated chip, including depositing an etch stop layer over a first region and a second region of the integrated chip; performing an etching process to define an opening in the etch stop layer in the first region; depositing a barrier layer over the etch stop layer and extending into the opening; depositing a first conductive layer over the etch stop layer, the first conductive layer having a protrusion demarcated by the opening in the etch stop layer and having a substantially constant first width; depositing a ferroelectric film over the first conductive layer; depositing a second conductive layer over the ferroelectric film; and patterning the first conductive layer, the ferroelectric film, the second conductive layer, and the barrier layer, the patterning defining a pad of the first conductive layer directly over the protrusion and the etch stop layer, the pad having a substantially constant second width greater than the first width and equal to a width of the patterned barrier layer.

In yet other embodiments, the present disclosure relates to an integrated chip, including a first wire level over a substrate; an etch stop layer overlying the first wire level; a conductive structure electrically coupled to the first wire level, wherein the conductive structure extends through the etch stop layer and overlies a top surface of the etch stop layer; a data storage layer overlying the conductive structure; a top electrode overlying the data storage layer, where the conductive structure, the data storage layer, and the top electrode define a memory cell; and a barrier layer separating the conductive structure from the etch stop layer, including from the top surface of the etch stop layer, and further separating the conductive structure from the first wire level.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a first wire over a substrate;
an etch stop layer overlying the first wire;
a conductive structure electrically coupled to the first wire, wherein the conductive structure extends through the etch stop layer and overlies a top surface of the etch stop layer;
a data storage layer overlying the conductive structure;
a top electrode overlying the data storage layer, where the conductive structure, the data storage layer, and the top electrode define a memory cell; and
a barrier layer separating the conductive structure from inner sidewalls and the top surface of the etch stop layer, and further separating the conductive structure from the first wire.

2. The integrated device of claim 1, wherein the barrier layer, the conductive structure, and the data storage layer form a common sidewall directly over the etch stop layer.

3. The integrated device of claim 2, wherein the barrier layer has an outer sidewall facing the same direction as the common sidewall and directly between inner sidewalls of the etch stop layer.

4. The integrated device of claim 1, wherein the conductive structure has a pad and a protrusion extending through the etch stop layer from the pad, wherein the protrusion has a substantially constant first width, and wherein the pad overlies the etch stop structure and the protrusion and has a substantially constant second width, wherein the second width is greater than the first width.

5. The integrated device of claim 4, wherein the barrier layer extends from an elevation level with a bottom surface of the etch stop layer to directly over the etch stop layer.

6. The integrated device of claim 4, wherein the barrier layer has a third width substantially equal to the second width.

7. An integrated device, comprising:
a first wire over a substrate;
a conductive structure electrically coupled to the first wire, wherein the conductive structure comprises a protrusion having a first width and a pad having a second width greater than the first width;
a ferroelectric layer on the conductive structure and having the second width; and
a top electrode on the ferroelectric layer and having a lower surface overlying the protrusion of the conductive structure.

8. The integrated device of claim 7, wherein the top electrode has a third width less than the second width and greater than the first width.

9. The integrated device of claim 7, further comprising a barrier layer covering lower surfaces of the conductive structure, wherein the barrier layer comprises first outer sidewalls facing away from and level with the protrusion and second outer sidewalls spaced by a distance substantially equal to the second width.

10. The integrated device of claim 7, further comprising an etch stop layer separating the pad of the conductive structure from the first wire, wherein the pad is vertically spaced from the etch stop layer and the protrusion of the conductive structure is level with the etch stop layer and laterally spaced from the etch stop layer.

11. The integrated device of claim 10, further comprising a barrier layer vertically separating a bottom surface of the pad from the etch stop layer and laterally separating sidewalls of the protrusion from the etch stop layer.

12. The integrated device of claim 11, wherein the barrier layer has a first sidewall on the first wire and a second sidewall on the etch stop layer.

13. The integrated device of claim 7, further comprising an etch stop layer contacting sidewalls of the pad and the ferroelectric layer, wherein the etch stop layer is spaced from the sidewalls of the protrusion by a barrier layer.

14. The integrated device of claim 13, wherein the etch stop layer is spaced from the sidewalls of the top electrode by an etch stop layer.

15. An integrated device, comprising:
a first wire over a substrate;
a first etch stop layer having a first material overlying the first wire;
a conductive structure electrically coupled to the first wire, wherein the conductive structure extends to a first depth within the first etch stop layer and overlies a top surface of the first etch stop layer;
a barrier layer having a conductive material separating the conductive structure from the first wire and the first etch stop layer;
a ferroelectric layer overlying the conductive structure and spaced from the barrier layer; and
a second etch stop layer on a top surface of the first etch stop layer and on sidewalls of both the conductive barrier layer and the ferroelectric layer.

16. The integrated device of claim 15, further comprising:
a top electrode on the ferroelectric layer and spaced from the first and second etch stop layers.

17. The integrated device of claim 15, wherein the conductive structure further comprises both:
a protrusion level with the first etch stop layer and separated from the first etch stop layer by the barrier layer; and
a pad level with the second etch stop layer, wherein the pad has both a bottom surface spaced from the first etch stop layer, and sidewalls contacting the second etch stop layer.

18. The integrated device of claim 15, wherein the barrier layer has a first sidewall level with and contacting a sidewall of the first etch stop layer and a second sidewall level with and contacting a sidewall of the second etch stop layer.

19. The integrated device of claim 15, wherein the barrier layer has both:
a first lower surface on the first wire and beneath a bottom surface of the conductive structure; and
a second lower surface on the first etch stop layer and above a bottom surface of the conductive structure.

20. The integrated device of claim 19, wherein the conductive structure, the barrier layer, and the ferroelectric layer have sidewalls contacting a sidewall of the second etch stop layer.
